(19) United States
(12) Patent Application Publication
(10) Pub. No.: US 2003/0010530 A1
(43) Pub. Date: Jan. 16, 2003

(54) Multilayer printed board

(76) Inventors: Wolfgang Scheel, Berlin (DE); Detlef Krabe, Markt Schwaben (DE); Manfred Cygon, Duren (DE); Mathias Dietz, Duren (DE)

Correspondence Address: Robert S. Swecker, BURNS, DOANE, SWECKER & MATHIS, L.L.P., P.O. Box 1404, Alexandria, VA, 22313-1404, US

(21) Appl. No.: 10/173,625

(22) Filed: Jun. 19, 2002

Related U.S. Application Data
(63) Continuation of application No. PCT/EP00/13121, filed on Dec. 21, 2000.

(30) Foreign Application Priority Data
Dec. 21, 1999 (DE) 199 61 842.9

(51) Int. Cl. H05K 1/16

(52) U.S. Cl. 174/260

(57) ABSTRACT

Disclosed is a multilayer printed board to be provided with electronic components, which has at least one layer whose thermal expansion behavior corresponds approximately to the thermal expansion behavior of the electronic components while at the same time substantially determining the thermal expansion behavior of the multilayer printed board.

### FIELD OF THE INVENTION

The present invention relates to a multilayer printed board to be provided with electronic components.

### BACKGROUND OF THE INVENTION

The increasing demand for electronic devices, greater function demands, miniaturization of components, which is closely linked to the further development in the component sector, and the demand for greater reliability have led to a wide spectrum of printed boards.

Particularly important for this is the printed board's dimensional stability (constant dimensions) if the board is exposed to thermal shock stress. The expansion coefficient a is considered as the criterium for the dimensional stability in dependence on temperature. For FR quality (fiber glass fabric/epoxy resin) printed board substrates, the expansion coefficient is 16-18 ppm/K. The expansion coefficient for SI chips is 3 ppm/K. Thus it is impossible to mount semiconductor chips directly on printed boards without additional aids (e.g. underfilling) and further development of printed boards for future system integration is therefore very restricted. In view of this situation, the structure of molded laminated materials must be modified in such a manner that their expansion coefficient corresponds approximately to the expansion coefficient of silicon.

Employed as a carrier material for molded laminated materials are paper and glass silk fabric, more rarely glass silk mats, nonwoven glass fiber and quartz-fiber-based fabric as well as aramide-fiber-based fabrics. The most common binder is an epoxy resin. If there is thermal shock stress during mounting or during operation, differences in the thermal longitudinal expansion coefficients of materials lead to thermally induced mechanical tensions in the circuit carrier as well as at the points of connection and at the points of contact, which lead to fatigue at the points of contact and in extreme cases to breaks in contact.

Typical examples of this problem are the differences in the expansion coefficients of an epoxy resin glass fabric as the base material for printed boards mounted with bare silicon chips respectively SMD components. When soldering, the difference between the longitudinal expansion coefficients in z-direction in the epoxy resin glass fabric can lead to tears in the metallization of the holes.

In order to overcome this problem, the expansion coefficients of the connection components have to be matched. Possible methods in use relating to fatigue at the points of contact are elastic connection component elements and underfilling bare chip structures.

The first possibility is not feasible with two-dimensional connections and the second possibility is an additional complicated process step.

Moreover, the integration of micronic function structures in multilayer printed boards is very expensive and complicated to realize.

### SUMMARY OF THE INVENTION

The object is to provide a multilayer printed board which has greater dimensional stability, as a result of which the connections to the electric components should be exposed to less thermal expansion stress.

The solution is set forth in claim 1. Advantageous further improvements of the present invention are the subject matter of the subclaims.

In order to master the problem, a printed board having greater dimensional stability is proposed which not only eliminates the basic drawbacks of the previous method of proceeding while making a substantially higher degree of system integration possible, e.g. with micronic function elements (optical, mechanical . . . ).

An element of the present invention is that the multilayer printed board to be provided with electronic components has at least one layer whose thermal expansion behavior corresponds approximately to the thermal expansion behavior of the electronic components while at the same time substantially determining the thermal expansion behavior of the multilayer printed board.

Especially suited is glass, particularly in the form of a thin glass film. Such type suited thin glass films can be obtained, for example, from the German firm DESAG under the item number AF45 and D263. Such type thin glass films are, in particular, borosilicate glass layers having a typical layer thickness of between 30 μm and 1.1 mm. Preferably suited for the aforementioned purpose, however, are thin glass films with thicknesses between 50 and 500 μm.

Other layer materials, such as glass composite materials or semiconductor materials, preferably the materials of which the components themselves are made, for example SI, can of course also be used.

### BRIEF DESCRIPTION OF THE DRAWING

The present invention is made more apparent by way of example in the following using a preferred embodiment with reference to the accompanying drawing without the intention of limiting the overall inventive idea.

FIG. 1 shows a cross section of a multilayer arrangement.

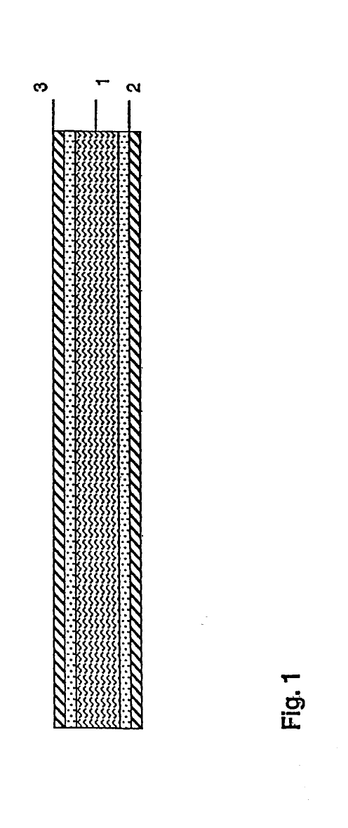

### DETAILED DESCRIPTION OF THE INVENTION

By means of pressing, a laminate is produced from a 100 μm thick glass film (1) together with a special epoxy-resin-based resin formula (2) and a 18 μm thick copper foil (3). The laminate has an overall thickness of 160 μm.

The expansion of the laminate was measured under a constant load (100 mN) by means of thermomechanical analysis (TMA) in dependence on temperature. The heating up time was 10° C./min.

The following values were determined for the expansion coefficients α:

-α1 (from 40° C. to Tg) 6.2 ppm/° C.

-α2 (from T§ to 195° C.) 4.3 ppm/° C.

-α3(from 40° C. to 195° C.) 5.3 ppm/° C.

List of Reference Numbers

1 glass film

2 resin layer

3 copper layer

What is claimed is:

1. A multilayer printed board to be provided with electronic components, which has at least one layer whose thermal expansion behavior corresponds approximately to the thermal expansion behavior of said electronic components while at the same time substantially determining the thermal expansion behavior of said multilayer printed board.

2. The multilayer printed board according to claim 1, wherein said layer is a glass layer or a layer having a glass content, which is intimately bonded to other layer materials.

3. The multilayer printed board according to claim 1, wherein said layer is a thin glass film.

4. The multilayer printed board according to claim 1, wherein said layer has a thickness of between 30 and 1100 μm.

5. The multilayer printed board according to claim 4, wherein said layer is between 50 and 500 μm thick.

6. A multilayer printed board according to claim 2, wherein said glass layer is a borosilicate glass layer.

7. The multilayer printed board according to claim 2, wherein said other layer materials are thermoplastic or duroplastic materials, metals or electrically conducting or electrically nonconducting plastics.

8. The multilayer printed board according to claim 1, wherein said layer is disposed inside or as external layer of said multilayer printed board.

9. The multilayer printed board according to claim 1, wherein said intimate bonding of the single layers of which said multilayer printed board is composed occurs by means of pressing to a molded laminated material.

10. The multilayer printed board according to claim 1, wherein said layer can be utilized as a reinforcement material for laminates and prepregs and/or as an external layer in combination with thermoplastic or duroplastic polymers.

11. The multilayer printed board according to claim 1, wherein said layer is perforable, porous, structurable for optical applications, printable, physically coatable, chemically coatable, roll-to-roll processable and/or thermally moldable.
